(19) United States
(12) Patent Application Publication
(10) Pub. No.: US 2026/0282645 A1
(43) Pub. Date: Sep. 17, 2026

(54) DISPLAY DEVICE AND METHOD FOR MANUFACTURING DISPLAY DEVICE

(71) Applicant: Sharp Display Technology Corporation, Kameyama City, Mie (JP)

(72) Inventor: Yunting UEDA, Kameyama City, Mie (JP)

(21) Appl. No.: 19/125,489

(22) PCT Filed: Nov. 4, 2022
(86) PCT No.: PCT/JP2022/041221

§ 371 Date: Apr. 29, 2025

(51) Int. Cl. H10K 50/115; H10K 59/12

(52) U.S. Cl. CPC H10K 50/115; H10K 59/1201

(57) ABSTRACT

A display device includes: a substrate; and a first light-emitting element and a second light-emitting element on the substrate, wherein the first light-emitting element has a first light-emitting layer containing: a first quantum dot; and a first ligand having a dipole moment in a direction from a main chain toward a coordinating functional group, and the second light-emitting element has a second light-emitting layer containing: a second quantum dot; and a second ligand having a dipole moment in a direction from a coordinating functional group toward a main chain.

### TECHNICAL FIELD

The present disclosure relates to a display device including a light-emitting element and a method for manufacturing the display device.

### BACKGROUND ART

Patent Document 1 discloses a method for forming a quantum dot layer on a substrate by electrophoretic deposition, using a solution containing a polarized solvent and quantum dots dispersed in the solvent.

### CITATION LIST

### Patent Literature

[Patent Document 1] Chinese Patent Application Publication No. 113809273

### SUMMARY

### Technical Problems

As to the method described in Patent Document 1, only the polarized solvent molecules could be adsorbed onto a substrate. Furthermore, as to the method described in Patent Document 1, the quantum dots might not be charged in some cases, and would not be efficiently adsorbed onto the substrate.

### Solution to Problems

A display device according to an aspect of the present disclosure includes: a substrate; and a first light-emitting element and a second light-emitting element on the substrate. The first light-emitting element has a first light-emitting layer containing: a first quantum dot; and a first ligand having a dipole moment in a direction from a main chain toward a coordinating functional group. The second light-emitting element has a second light-emitting layer containing: a second quantum dot; and a second ligand having a dipole moment in a direction from a coordinating functional group toward a main chain.

A display device according to another embodiment of the present disclosure includes: a substrate; and a plurality of light-emitting elements above the substrate. Each of the light-emitting elements has: a light-emitting layer containing quantum dots; and a high dielectric layer positioned toward the substrate with respect to the light-emitting layer.

A display device according to yet another embodiment of the present disclosure includes: a substrate; and a first light-emitting element and a second light-emitting element on the substrate. The first light-emitting element has: a first light-emitting layer containing a first quantum dot, and a first ligand having a dipole moment in a direction from a main chain toward a coordinating functional group; and a first high dielectric layer positioned toward the substrate with respect to the first light-emitting layer. The second light-emitting element has: a second light-emitting layer containing a second quantum dot, and a second ligand having a dipole moment in a direction from a coordinating functional group toward a main chain; and a second high dielectric layer positioned toward the substrate with respect to the second light-emitting layer.

A method for manufacturing a display device according to an embodiment of the present disclosure includes: preparing a substrate layer; forming a first electrode and a second electrode to the substrate; forming high dielectric layers to the substrate, each of the high dielectric layers overlapping with a corresponding one of the first electrode and the second electrode in a plan view of the substrate; synthesizing a first solution containing a first quantum dot and a first ligand having a dipole moment in a direction from a main chain toward a coordinating functional group; synthesizing a second solution containing a second quantum dot and a second ligand having a dipole moment in a direction from a coordinating functional group toward a main chain; immersing, in the first solution, the substrate to which the high dielectric layers are formed; applying a voltage to at least one of the first electrode or the second electrode of the substrate immersed in the first solution so that the first quantum dot is adsorbed onto the high dielectric layer overlapping with the first electrode in a plan view of the substrate; immersing, in the second solution, the substrate to which the high dielectric layers are formed; and applying a voltage to at least one of the first electrode or the second electrode of the substrate immersed in the second solution so that the second quantum dot is adsorbed onto the high dielectric layer overlapping with the second electrode in a plan view of the substrate.

### Advantageous Effect of Disclosure

The present disclosure provides a display device including a light-emitting element for which a light-emitting layer can be formed by electrodeposition with efficiency.

### BRIEF DESCRIPTION OF DRAWINGS

FIG. 1A illustrates a schematic sectional side view of a display device according to a first embodiment.

FIG. 1B illustrates schematic diagrams of quantum-dot structures according to a first embodiment.

FIG. 2 illustrates a schematic plan view of the display device according to the first embodiment.

FIG. 3 is a flowchart showing a method for manufacturing the display device according to the first embodiment.

FIG. 4A illustrates a cross-sectional view of the step S7 included in the method for manufacturing the display device according to the first embodiment.

FIG. 4B illustrates a cross-sectional view of the step S8 included in the method for manufacturing the display device according to the first embodiment.

FIG. 5A illustrates a cross-sectional view of the step S11 included in the method for manufacturing the display device according to the first embodiment.

FIG. 5B illustrates a cross-sectional view of the step S12 included in the method for manufacturing the display device according to the first embodiment.

FIG. 6A illustrates a cross-sectional view of the step S13 included in the method for manufacturing the display device according to the first embodiment.

FIG. 6B illustrates a cross-sectional view of the step S14 included in the method for manufacturing the display device according to the first embodiment.

FIG. 7A illustrates a cross-sectional view of the step S15 included in the method for manufacturing the display device according to the first embodiment.

FIG. 7B illustrates a cross-sectional view of the step S16 included in the method for manufacturing the display device according to the first embodiment.

FIG. 8 illustrates equivalent circuit diagrams of pixel circuits and anodes of the display device according to the first embodiment.

FIG. 9 illustrates a schematic sectional side view of a display device according to a second embodiment.

### DESCRIPTION OF EMBODIMENTS

### First Embodiment

### Display Device: Outline

Described below is an embodiment of the present disclosure with reference to the drawings. Note that, throughout the drawings, like reference signs designate identical constituent features. Such constituent features will not be elaborated upon.

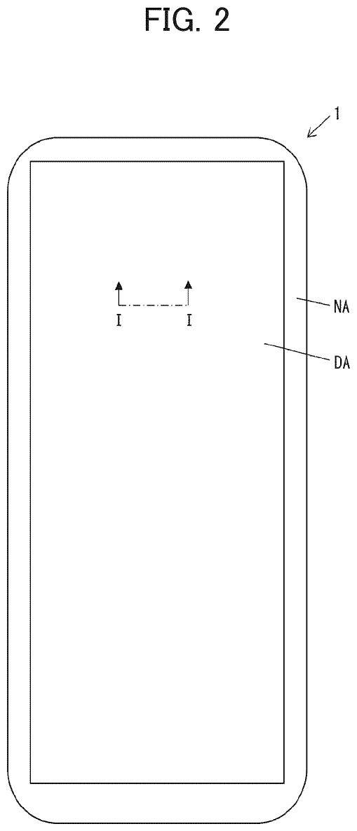

FIG. 2 illustrates a schematic plan view of a display device according to this embodiment. A display device 1 is a device to be used for a display of such an appliance as, for example, a TV or a smartphone. The display device 1 includes: a display unit DA; and a picture-frame unit NA formed around an outer periphery of the display unit DA. The display device 1 controls light emitted from each of a plurality of light-emitting elements formed in the display unit DA. Hence, the display device 1 displays an image on the display unit DA. The light-emitting elements will be described later. The picture-frame unit NA may have such a unit as a driver formed to drive each of the plurality of light-emitting elements in the display unit DA.

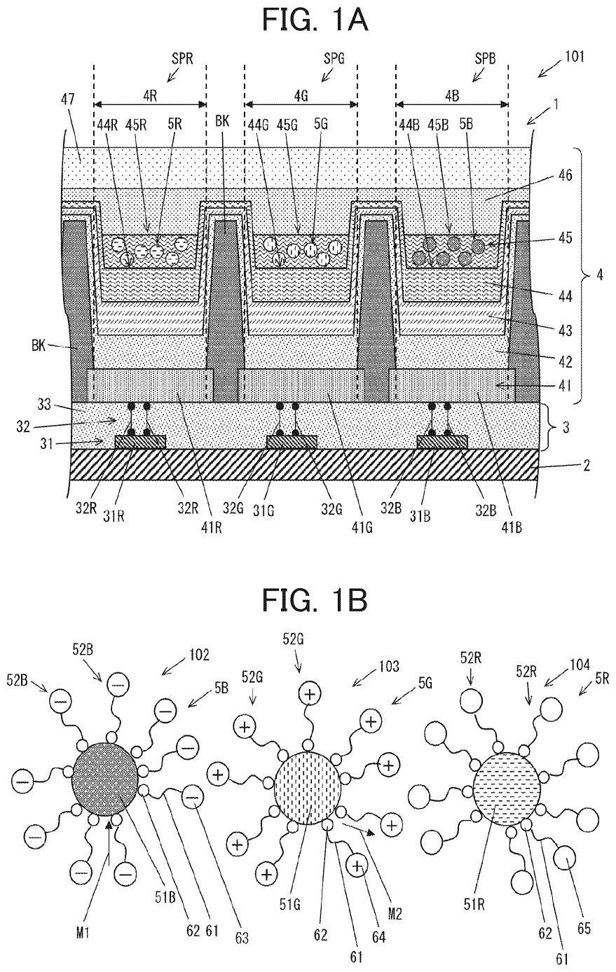

FIG. 1A illustrates a schematic sectional side view 101 of the display device and FIG. 1B illustrates a schematic diagram 102, a schematic diagram 103, and a schematic diagram 104 of quantum-dot structures according to this embodiment. In the present disclosure, the direction from a substrate 2 toward a light-emitting element 4 of the display device 1 is referred to as “upwards”, and the direction opposite to “upwards” is referred to as “downwards”. The substrate 2 and the light-emitting element 4 will be described later.

The schematic sectional side view 101 is a cross-sectional view taken along arrows I-I in FIG. 2. In particular, the schematic sectional side view 101 is a view showing a cross-section across a blue subpixel SPB, a green subpixel SPG, and a red subpixel SPR in a plan view of the substrate 2 of the display device 1 according to this embodiment. The subpixels SPB, SPG, and SPR will be described later. The schematic diagram 102, the schematic diagram 103, and the schematic diagram 104 respectively illustrate, under magnification, a blue quantum-dot structure 5B, a green quantum-dot structure 5G, and a red quantum-dot structure 5R, all of which will be described later.

As illustrated in the schematic sectional side view 101, the display device 1 includes: the substrate 2; a pixel circuit layer 3; and the light-emitting element 4. The display device 1 includes: the blue subpixel SPB in which a blue light-emitting element 4B to be described later is formed; the green subpixel SPG in which a green light-emitting element 4G is formed; and the red subpixel SPR in which a red light-emitting element 4R is formed, all of which are arranged in a plan view of the substrate 2. The blue light-emitting element 4B, the green light-emitting element 4G, and the red light-emitting element 4R respectively emit a blue light, a green light, and a red light. Hence, the display device 1 individually controls the above light-emitting elements, using, for example, such a unit as a not-shown driver, so as to display a color image.

Note that, in this embodiment, the blue light has a center wavelength in a wavelength band of, for example, 380 nm or more and 500 nm or less. Furthermore, the green light has a center wavelength in a wavelength band of, for example, more than 500 nm and 600 nm or less. Moreover, the red light has a center wavelength in a wavelength band of more than 600 nm and 780 nm or less.

### Display Device: Substrate and Pixel Circuit Layer

In this embodiment, the substrate 2 may be, for example, a hard substrate such as a glass substrate. Alternatively, the substrate 2 may be a flexible substrate such as a film substrate.

The pixel circuit layer 3 includes: a plurality of pixel circuits 31 formed on the substrate 2; a contact portion 32 electrically connecting each of pixel circuits 31 to a corresponding one of anodes 41 to be described later; and a planarization film 33 planarizing the pixel circuit layer 3.

The pixel circuits 31 includes: a pixel circuit 31B formed in the blue subpixel SPB; a pixel circuit 31G formed in the green subpixel SPG; and a pixel circuit 31R formed in the red subpixel SPR. The contact portion 32 includes: a contact portion 32B formed in the blue subpixel SPB; a contact portion 32G formed in the green subpixel SPG; and a contact portion 32R formed in the red subpixel SPR. Each of the pixel circuits 31 is individually driven by a not-shown driver, and individually applies a voltage to the anode 41 of a corresponding one of a plurality of the light-emitting elements 4 through the respective contact portions 32.

The planarization film 33 is, for example, an organic film such as polyimide. The planarization film 33 planarizes an upper face of the pixel circuit layer 3 on which the light-emitting element 4 is formed. The contact portion 32 may be formed in a contact hole formed in the planarization film 33.

### Display Device: Light-Emitting Element: Outline

The light-emitting element 4 includes: the anode 41; a hole injection layer 42; a hole transport layer 43; a high dielectric layer 44; a light-emitting layer 45; an electron transport layer 46; and a cathode 47, all of which are stacked on top of another in the stated order above the pixel circuit layer 3. Note that, in this embodiment, the light-emitting element 4 shall not be limited to the above configuration as long as the high dielectric layer 44 is positioned toward the substrate 2 with respect to the light-emitting layer 45. For example, the light-emitting element 4 may include: the cathode 47; the electron transport layer 46; the high dielectric layer 44; the light-emitting layer 45; the hole transport layer 43; the hole injection layer 42; and the anode 41, all of which are stacked on top of another in the stated order above the pixel circuit layer 3.

The light-emitting element 4 has: the blue light-emitting element 4B serving as a first light-emitting element; the green light-emitting element 4G serving as a second light-emitting element; and a red light-emitting element 4R serving as a third light-emitting element. As described above, the blue light-emitting element 4B is formed in the blue subpixel SPB, the green light-emitting element 4G is formed in the green subpixel SPG, and the red light-emitting element 4R is formed in the red subpixel SPR.

Furthermore, the display device 1 includes a bank BK on the pixel circuit layer 3. The bank BK may be an insulating layer capable of either absorbing or blocking visible light. Examples of a material of the bank BK include a photosensitive resin containing a light-absorbing agent such as carbon black. Examples of the photosensitive resin include photosensitive organic insulating materials such as polyimide and acrylic resin. The bank BK partitions the plurality of light-emitting elements 4 from one another. In particular, the bank BK is formed among the plurality of anodes 41 in a plan view of the substrate 2. In this embodiment, the light-emitting layer 45 is partitioned by the bank BK for each of the subpixels. Note that the hole injection layer 42, the hole transport layer 43, the high dielectric layer 44, the electron transport layer 46, and the cathode 47 are formed in common to the plurality of subpixels. Note that, the hole injection layer 42, the hole transport layer 43, the high dielectric layer 44, the electron transport layer 46, and the cathode 47 may also be partitioned by the bank BK for each of the subpixels.

The bank BK may be formed at a position for covering an end portion of each anode 41. In other words, the bank BK may have an opening in a portion overlapping with the anode 41 in a plan view of the substrate 2. In this case, the bank BK can reduce an influence, of electric field concentration at the end portion of the anode 41 in each light-emitting element 4, on injection of holes from the anode 41 into the light-emitting layer 45.

The blue light-emitting element 4B includes: an anode 41B; the hole injection layer 42; the hole transport layer 43; the high dielectric layer 44; a blue light-emitting layer 45B; the electron transport layer 46; and the cathode 47, all of which overlap with the blue subpixel SPB in a plan view of the substrate 2. The green light-emitting element 4G includes: an anode 41G; the hole injection layer 42; the hole transport layer 43; the high dielectric layer 44; a green light-emitting layer 45G; the electron transport layer 46; and the cathode 47, all of which overlap with the green subpixel SPG in the plan view of the substrate 2. The red light-emitting element 4R includes: an anode 41R; the hole injection layer 42; the hole transport layer 43; the high dielectric layer 44; a red light-emitting layer 45R; the electron transport layer 46; and the cathode 47, all of which overlap with the red subpixel SPR in the plan view of the substrate 2.

In particular, the blue light-emitting element 4B includes: the anode 41B serving as a first electrode; and the blue light-emitting layer 45B serving as a first light-emitting layer. Furthermore, the green light-emitting element 4G includes: the anode 41G serving as a second electrode; and the green light-emitting layer 45G serving as a second light-emitting layer. Moreover, the red light-emitting element 4R includes: the anode 41R serving as a third electrode; and the red light-emitting layer 45R serving as a third light-emitting layer.

### Display Device: Light-Emitting Element: Anode and Cathode

At least one of the anode 41 or the cathode 47 is a transparent electrode that transmits visible light. The transparent electrode may be formed of, for example, ITO, InZnO, SnO₂, or FTO. Furthermore, one of the anode 41 or the cathode 47 may be a reflective electrode. The reflective electrode may contain a metal material highly reflective to visible light. The metal material may be either a single-component metal such as, for example, Al, Ag, Cu, or Au, or an alloy of these metals. The anode 41 may contain the same material, or different materials from one another, among the plurality of light-emitting elements 4.

Each of the anodes 41 is electrically connected to a corresponding one of the pixel circuits 31 through the respective contact portions 32. Furthermore, each cathode 47 receives a predetermined voltage from, for example, a not-shown auxiliary power supply. Hence, the display device 1 causes a not-shown driver to control a voltage to be applied to each anode 41 through the corresponding pixel circuit 31, so as to individually control light emitted from each light-emitting element 4.

In particular, in this embodiment, the pixel circuit 31B electrically connected to the anode 41B serving as the first electrode is a first pixel circuit. Furthermore, in this embodiment, the pixel circuit 31G electrically connected to the anode 41G serving as the second electrode is a second pixel circuit.

### Display Device: Light-Emitting Element: Hole Injection Layer, Hole Transport Layer, and Electron Transport Layer

The hole injection layer 42 is a layer for injecting holes, which are from the anode 41, into a layer toward the light-emitting layer 45 with respect to the anode 41. The hole injection layer 42 electrically connects to each anode 41 through an opening of the bank BK. The hole injection layer 42 may be made of a known organic or inorganic material capable of transporting the holes and used for light-emitting elements containing quantum dots. Examples of a material of the hole injection layer 42 include: a composite (abbreviated as “PEDOT:PSS”) containing poly(3,4-ethylenedioxythiophene) (PEDOT) and polystyrene sulphonate (PSS); nickel oxide (NiO); and copper thiocyanate (CuSCN). Note that these materials may be used alone or in combination of two or more as appropriate.

The hole transport layer 43 is a layer for transporting the holes, which are injected from the anode 41 into the hole injection layer 42, toward the light-emitting layer 45. The hole transport layer 43 may be made of a known organic or inorganic material capable of transporting the holes and used for light-emitting elements containing quantum dots. Examples of a material of the hole transport layer 43 include: poly [(9,9-dioctylfluorenyl-2,7-diyl)-co-(4,4′-(N-(4-sec-butylphenyl))diphenylamine)] (abbreviated as “TFB”); poly [N,N′-bis(4-butylphenyl)-N,N′-bis(phenyl)-benzidine] (abbreviated as “p-TPD”); and polyvinyl carbazole (abbreviated as “PVK”). These materials may also be used alone or in combination of two or more as appropriate.

The electron transport layer 46 transports electrons, which are injected from the cathode 47, to the light-emitting layer 45. The electron transport layer 46 may be made of a known organic or inorganic material capable of transporting the electrons and used for light-emitting elements containing quantum dots. Examples of a material of the electron transport layer 46 include: zinc oxide (ZnO) nanoparticles; zinc magnesium oxide (MgZnO) nanoparticles; and 2,2′,2″-(1,3,5,-benzinetriyl)-tris(1-phenyl-1-H-benzimidazole) (abbreviated as “TPBi”). These materials may also be used alone or in combination of two or more as appropriate.

The hole injection layer 42, the hole transport layer 43, and the electron transport layer 46 may contain the same material, or different materials from one another, among the plurality of light-emitting elements 4. In particular, in order to improve efficiency in injecting the holes and the electrons into each of the light-emitting layers 45, the materials of the hole injection layer 42, the hole transport layer 43, and the electron transport layer 46 of each light-emitting element 4 may be selected in accordance with a bandgap of the material of each light-emitting layer 45. Furthermore, the hole injection layer 42, the hole transport layer 43, and the electron transport layer 46 may be formed in common to the plurality of subpixels, and may be formed, for example, above an upper face of the bank BK.

### Display Device: Light-Emitting Element; High Dielectric Layer

The high dielectric layer 44 is positioned toward the substrate 2 with respect to the light-emitting layer 45. The high dielectric layer 44 may be formed, for example, between the hole transport layer 43 and the light-emitting layer 45. In particular, the high dielectric layer 44 may be in contact with the light-emitting layer 45. A relative permittivity of the high dielectric layer 44 is higher than a relative permittivity of each of the layers included in the light-emitting element 4 and positioned toward the substrate 2 with respect to the high dielectric layer 44. Specifically, the relative permittivity of the high dielectric layer 44 is higher than the relative permittivity of the hole injection layer 42 and the relative permittivity of the hole transport layer 43. Furthermore, the relative permittivity of the high dielectric layer 44 is higher than the relative permittivity of the bank BK.

The high dielectric layer 44 may contain at least one of silicon oxide, silicon nitride, or an oxide of a group 4 element. The silicon oxide contains, for example, SiO₂. The silicon nitride contains, for example, SiN. The oxide of the group 4 element contains, for example, hafnium oxide such as HfO₂. When the high dielectric layer 44 contains the silicon oxide, the silicon nitride, or the oxide of the group 4 element, the high dielectric layer 44 can achieve both an increase in relative permittivity and a reduction in costs.

The high dielectric layer 44 may have a thickness to such an extent that the holes to be transported from the hole transport layer 43 to the light-emitting layer 45 can pass through the high dielectric layer 44 by tunneling. For example, the high dielectric layer 44 may have a thickness of 1 nm or more and 100 nm or less. When the thickness of the high dielectric layer 44 is 100 nm or less, the high dielectric layer 44 can be effectively kept from blocking transportation of the holes from the hole transport layer 43 to the light-emitting layer 45. When the thickness of the high dielectric layer 44 is 1 nm or more, the high dielectric layer 44 can be formed well.

In this embodiment, the high dielectric layer 44 includes: a high dielectric layer 44B serving as a first high dielectric layer positioned in the blue subpixel SPB; a high dielectric layer 44G serving as a second high dielectric layer positioned in the green subpixel SPG; and a high dielectric layer 44R positioned in the red subpixel SPR. Each of the high dielectric layer 44B, the high dielectric layer 44G, and the high dielectric layer 44R may be portions of the high dielectric layer 44 in common to the plurality of subpixels. Hence, the high dielectric layers 44 may contain the same material, or different materials from one another, among the plurality of light-emitting elements 4. Furthermore, in this embodiment, the red light-emitting element 4R may omit the high dielectric layer 44R.

### Display Device: Light-Emitting Element: Light-Emitting Layer: Quantum Dots

The light-emitting layer 45 includes, as described above, the blue light-emitting layer 45B, the green light-emitting layer 45G, and the red light-emitting layer 45R. The blue light-emitting layer 45B, the green light-emitting layer 45G, and the red light-emitting layer 45R are formed at respective positions each overlapping with a corresponding one of the blue subpixel SPB, the green subpixel SPG, and the red subpixel SPR in a plan view of the substrate 2.

Each of the light-emitting layers 45 includes a plurality of quantum dot structures. Each of the quantum-dot structures includes: a quantum dot; and ligands each having a coordinating functional group capable of coordinating with the quantum dot. In particular, the blue light-emitting layer 45B includes a plurality of blue quantum-dot structures 5B. The green light-emitting layer 45G includes a plurality of quantum-dot structures 5G. The red light-emitting layer 45R includes a plurality of quantum-dot structures 5R. The plurality of quantum-dot structures in each light-emitting layer 45 may be arranged irregularly as illustrated in the schematic sectional side view 101. Alternatively, the plurality of quantum-dot structures may be arranged regularly.

Described below will be a quantum-dot structure included in each light-emitting layer 45, with reference to the schematic diagram 102, the schematic diagram 103, and the schematic diagram 104 in FIG. 1B. As illustrated in the schematic diagram 102, the blue quantum-dot structure 5B includes: a blue quantum dot 51B serving as a first quantum dot; and first ligands 52B. As illustrated in the schematic diagram 103, the green quantum-dot structure 5G includes: a green quantum dot 51G serving as a second quantum dot; and second ligands 52G. As illustrated in the schematic diagram 104, the red quantum-dot structure 5R includes: a red quantum dot 51R serving as a third quantum dot; and third ligands 52R.

Each of the blue quantum dot 51B, the green quantum dot 51G, and the red quantum dot 51R includes at least a core. Injected into the core of each quantum dot are holes from the anode 41 and electrons from the cathode 47. When the holes and the electrons recombine together, excitons are generated to emit light. The blue quantum dot 51B, the green quantum dot 51G, and the red quantum dot 51R emit a blue light, a green light, and a red light from the respective cores.

Note that, in the present disclosure, the “quantum dots” are dots each having a maximum width of 100 nm or less. A quantum dot may have any given shape as long as the maximum width of the quantum dot is within the above range. The shape of the quantum dot shall not be limited to a spherical shape (a circular cross-section). The quantum dot may have, for example, a polygonal cross-section, a bar-like three dimensional shape, a branch-like three dimensional shape, or a three dimensional shape having asperities on the surface. Alternatively, the quantum dot may have a combination of those shapes.

The quantum dots may be typically made of a semiconductor. The semiconductor may have a certain bandgap. The semiconductor may be any given material capable of emitting light, and may include at least materials to be described below. The semiconductor may be capable of emitting a blue light, a green light, and a red light. The semiconductor includes at least one selected from the group consisting of, for example, a group II-VI compound, a group III-V compound, a chalcogenide, and a perovskite compound. Note that the group II-VI compound means a compound containing a group II element and a group VI element, and the group III-V compound means a compound containing a group III element and a group V element. Moreover, the group II element may include a group 2 element and a group 12 element, the group III element may include a group 3 element and a group 13 element, the group V element may include a group 5 element and a group 15 element, and the group VI element may include a group 6 element and a group 16 element.

The group II-VI compound includes at least one selected from the group consisting of, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

The group III-V compound includes at least one selected from the group consisting of, for example, GaAs, GaP, InN, InAs, InP, and InSb.

The chalcogenide is a compound containing a VI A (16) group element, and includes, for example, CdS or CdSe. The chalcogenide may contain a mixed crystal of these elements.

The perovskite compound has a composition represented by, for example, a general formula CsPbX₃. The constituent element X includes at least one selected from the group consisting of, for example, Cl, Br, and I.

Here, the group numbers of the elements in Roman numbers are denoted by the former International Union of Pure and Applied Chemistry (IUPAC) notation or by the former Chemical Abstracts Service (CAS) notation. The group numbers of the elements in Arabic numbers are denoted by the current IUPAC notation.

Each of the blue quantum dot 51B, the green quantum dot 51G, and the red quantum dot 51R may have, as referred to as, a core-shell structure including a shell positioned at least partially around the core. The shell of each quantum dot may have a function of protecting the core, such as compensating for defects in the core of the quantum dot. Otherwise, each of the blue quantum dot 51B, the green quantum dot 51G, and the red quantum dot 51R may have various kinds of known structures as a structure of a quantum dot.

### Display Device; Light-Emitting Element: Light-Emitting Layer: Ligands

Each of the first ligands 52B, the second ligands 52G, and the third ligands 52R has: a main chain 61 that is, for example, a carbon chain; and a coordinating functional group 62 positioned at one end of the main chain 61. The coordinating functional group 62 is a functional group capable of coordinating and connecting to an outermost peripheral surface of the blue quantum dot 51B, the green quantum dot 51G, and the red quantum dot 51R.

In the present disclosure, the main chain 61 may be a neutral nonpolar molecule that does not ionize even in a polar solvent. The main chain 61 includes, for example, a carbon chain. The coordinating functional group 62 is a functional group polarized to such an extent that the coordinating functional group 62 can form a coordinate with the quantum dot. Note that, when a cross-section of the light-emitting layer 45 is observed, if a ligand is observed within 10 nm from an outermost peripheral surface of the quantum dot, the ligand may be seen to be coordinated to the quantum dot.

The first ligand 52B has an acidic group 63 at an end of the main chain 61 across from the coordinating functional group 62. The acidic group 63 is a functional group that is negatively charged in a polar medium such as, for example, water when releasing a proton into the polar medium. The first ligand 52B may contain the acidic group 63 losing a proton and negatively charged. The acidic group 63 contains, for example, a carbonyl group, a phosphite group, an aldehyde group, or a sulfonyl group. For example, the first ligand 52B may contain a polyethylene glycol carboxylic acid represented by a chemical formula below. In this case, the first ligand 52B contains a carbonyl group serving as the acidic group 63.

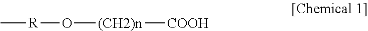

Note that, in the above chemical formula, ‘R’ is a substituent containing hydrocarbon, and ‘n’ is a degree of polymerization, and is, for example, an integer of 1 or more and 12 or less. The first ligand 52B containing polyethylene glycol carboxylic acid releases a proton into a polar solvent such as water. Then, the first ligand 52B is negatively charged as represented by a chemical formula below.

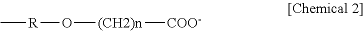

Hence, the first ligand 52B is a polar molecule whose atomic orbital is disproportionately positioned closer toward the acidic group 63 than toward the coordinating functional group 62 of the main chain 61. In particular, in this embodiment, a magnitude of a dipole moment caused by the acidic group 63 is sufficiently larger than a magnitude of a dipole moment caused by the coordinating functional group 62. Thus, the first ligand 52B has a dipole moment M1 in a direction from the main chain 61 toward the coordinating functional group 62 as a whole.

The second ligand 52G has a basic group 64 at an end of the main chain 61 across from the coordinating functional group 62. The basic group 64 is a functional group that is positively charged in a polar medium such as, for example, water when receiving a proton from the polar medium. The second ligand 52G may contain the basic group 64 obtaining a proton and positively charged. The basic group 64 contains, for example, an imino group, a hydroxy group, an amino group, a hydroxy group, or an alkoxide group. For example, the second ligand 52G may contain imine represented by a chemical formula below. In this case, the second ligand 52G contains an imino group serving as the basic group 64.

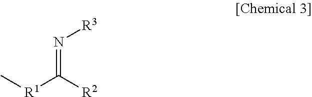

Note that, in the above chemical formula, ‘R¹’, ‘R²’, and ‘R³’ are substituents containing carbon hydrogen, and may be either the same or different from one another. The second ligand 52G containing imine receives a proton from a polar solvent such as water. Then, the second ligand 52G is positively charged as represented by a chemical formula below.

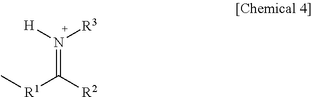

Hence, the second ligand 52G is a polar molecule whose atomic orbital is disproportionately positioned closer toward the coordinating functional group 62 than toward the basic group 64 of the main chain 61. In particular, in this embodiment, a magnitude of a dipole moment caused by the basic group 64 is sufficiently larger than a magnitude of a dipole moment caused by the coordinating functional group 62. Thus, the second ligand 52G has a dipole moment M2 in a direction from the coordinating functional group 62 toward the main chain 61 as a whole.

The third ligand 52R has a neutral group 65 at an end of the main chain 61 across from the coordinating functional group 62. The neutral group 65 is a functional group in which a proton is neither provided to nor received from a polar solvent such as, for example, water in the polar medium, or a proton is provided and received in equilibrium. Hence, the third ligand 52R is not charged in the polar solvent and is neutral. The neutral group 65 contains, for example, an alkyl group or an allyl group. Hence, the third ligand 52R is a non-polar molecule whose atomic orbital is less likely to be disproportionately positioned as a whole. For example, the third ligand 52R is a molecule that can be dispersed in, for example, water.

In this embodiment, the first ligand 52B and the second ligand 52G shall not be limited to have the above configurations. In this embodiment, the first ligand 52B may be a polar molecule having the dipole moment M1, and the second ligand 52G may be a polar molecule having the dipole moment M2. As long as the above configurations are satisfied, the first ligand 52B and the second ligand 52G do not have to be charged in a polar solvent.

### Method for Manufacturing Display Device: Until Forming Red Light-Emitting Layer

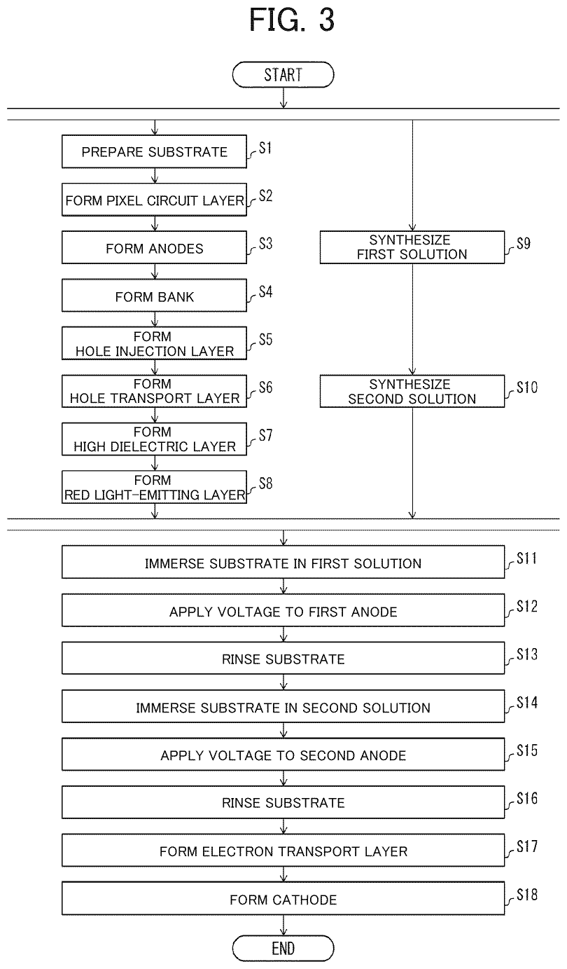

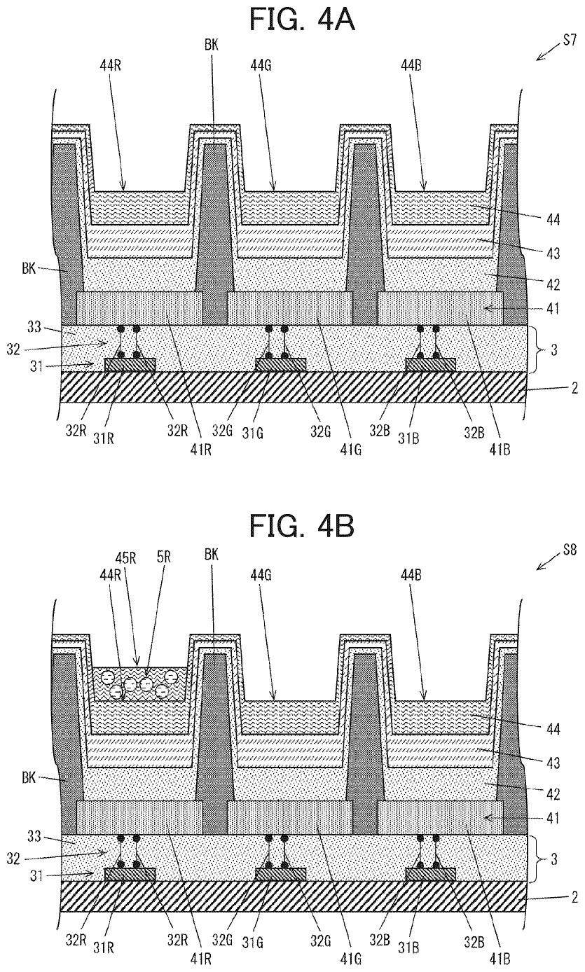

A method for manufacturing the display device 1 according to this embodiment will be described in detail, with reference to FIG. 3 to FIG. 7B. FIG. 3 is a flowchart showing a method for manufacturing the display device 1 according to this embodiment. FIG. 4A to FIG. 7B illustrate cross-sectional views of steps of producing the display device 1 according to this embodiment. The cross-sectional views illustrate a cross-section of the display device 1 corresponding to the cross-section of the display device 1 illustrated in the schematic sectional side view 101 in FIG. 1A.

In the method for manufacturing the display device 1 according to this embodiment, first, the substrate 2 is prepared (Step S1). In the preparation of the substrate 2, the substrate 2 may be formed of, for example, a glass substrate or a film substrate cut into a predetermined shape. Alternatively, the substrate 2 may be prepared in a large size. After the steps are carried out, the large substrate 2 may be cut out and divided into a plurality of the display devices 1.

Next, on the substrate 2, the pixel circuit layer 3 is formed (Step S2). Step S2 may be carried out as follows. For example, the pixel circuit 31 is formed at a position overlapping with each of the subpixels on the substrate 2 in a plan view of the substrate 2. The planarization film 33 is formed by application or deposition. After that, the contact portion 32 is formed in the planarization film 33. In forming the contact portion 32, a portion included in the planarization film 33 and overlapping with the pixel circuit 31 in a plan view of the substrate 2 is, for example, etched, so that a contact hole is formed. After that, in the contact hole, a conductive material is deposited by such a technique as sputtering to form the contact portion 32.

Next, on the pixel circuit layer 3, the anodes 41 are formed (Step S3). In forming the anodes 41, for example, a thin film of such a material as a metal material may be deposited on the pixel circuit layer 3 by such a technique as sputtering. After that, the thin film may be patterned by such a technique as dry-etching to form the anodes 41. Hence, at Step S3, the anode 41B serving as the first electrode is formed at a position overlapping with the blue subpixel SPB in a plan view of the substrate 2, and the anode 41G serving as the second electrode is formed at a position overlapping with the green subpixel SPG in a plan view of the substrate 2.

At Step S3, each of the anodes 41 is formed at a position overlapping with a corresponding one of the contact portions 32 in a plan view of the substrate 2. Thus, each of the anodes 41 is electrically connected to a corresponding one of the pixel circuits 31 through the respective contact portions 32. In particular, when the anode 41B serving as the first electrode is formed to the substrate 2, the anode 41B and the pixel circuit 31B serving as the first pixel circuit are electrically connected together. Furthermore, when the anode 41G serving as the second electrode is formed to the substrate 2, the anode 41G and the pixel circuit 31G serving as the second pixel circuit are electrically connected together.

Next, on the pixel circuit layer 3 and the anode 41, the bank BK is formed (Step S4). In forming the bank BK, for example, a photosensitive resin material may be applied and deposited above the substrate 2 and on the anode 41. After that, an opening may be provided by such a technique as photolithography to the photosensitive resin material at a position overlapping with the anode 41 in a plan view of the substrate 2. Thus, the bank BK is formed.

Next, on the anode 41, the hole injection layer 42 is formed (Step S5). In forming the hole injection layer 42, for example, a hole-transporting material may be applied and deposited on the anode 41 and between the banks BK in a plan view of the substrate 2 by such a technique as inkjet printing, so as to form the hole injection layer 42. Alternatively, in forming the hole injection layer 42, for example, a hole-transporting material may be applied and deposited on the anode 41 and the bank BK by such a technique as spin coating, so as to form the hole injection layer 42.

Next, on the hole injection layer 42, the hole transport layer 43 is formed (Step S6). In forming the hole transport layer 43, for example, as seen at Step S6, a hole-transporting material may be applied and deposited at a position on the hole injection layer 42, so as to form the hole transport layer 43.

Next, on the hole transport layer 43, the high dielectric layer 44 is formed (Step S7). In forming the high dielectric layer 44, for example, a material with a high permittivity may be applied and deposited on the hole transport layer 43 and between the banks BK in a plan view of the substrate 2 by such a technique as inkjet printing, so as to form the high dielectric layer 44. Alternatively, in forming the high dielectric layer 44, for example, the material with a high permittivity may be applied and deposited on the hole transport layer 43 and the bank BK by such a technique as spin coating, so as to form the high dielectric layer 44. When Step S7 ends, a multilayer stack is formed to include the substrate 2 shown at Step S7 in FIG. 4A.

In particular, at Step S7, in a plan view of the substrate 2, the high dielectric layer 44B is formed to overlap with the anode 41B and the high dielectric layer 44G is formed to overlap with the anode 41G. Furthermore, in this embodiment, as can be seen, the high dielectric layer 44 is formed before the light-emitting layer 45 is formed. Hence, in the display device 1 manufactured by the method for manufacturing the display device 1 according to this embodiment, the high dielectric layer 44 is positioned toward the substrate 2 with respect to the light-emitting layer 45.

Next, in this embodiment, the red light-emitting layer 45R of the light-emitting layer 45 is formed first (Step S8). In forming the red light-emitting layer 45R, for example, a solution in which the red quantum-dot structures 5R are dispersed in a solvent may be applied and deposited above the hole transport layer 43 and between the banks BK in a plan view of the substrate 2 by such a technique as inkjet printing. The solution may be dried to form the red light-emitting layer 45R. In the solution in which the red quantum-dot structures 5R are dispersed, the third ligands 52R may have a concentration of 1 to 100 mg/mL. Thus, as illustrated at Step S8 in FIG. 4B, the red light-emitting layer 45R is formed to contain the plurality of red quantum-dot structures 5R.

Alternatively, the red light-emitting layer 45R may be formed by a lift-off technique using a sacrificial layer. In this case, first, for example, a photosensitive resin material is applied, deposited, and patterned by photolithography, so as to form the sacrificial layer at a position except for the red subpixel SPR in a plan view of the substrate 2. Next, the solution containing the red quantum-dot structures 5R is applied and deposited by such a technique as spin coating. The solution is dried to form a layer containing the red quantum-dot structures 5R. Next, the sacrificial layer is rinsed with a suitable rinsing solution and removed together with red quantum-dot structures 5R above the sacrificial layer. Thus, the layer containing the red quantum-dot structures 5R can be left only in the red subpixel SPR, so that the red light-emitting layer 45R can be formed.

### Method for Manufacturing Display Device: Synthesizing Quantum Dot Material

In the method for manufacturing the display device 1 according to this embodiment, between Step S1 and the end of Step S8, a step is carried out to synthesize a solution to be used for forming the blue light-emitting layer 45B and the green light-emitting layer 45G.

For example, in this embodiment, a first solution is synthesized (Step S9) in parallel with steps from Step S1 to Step S8. The first solution is a solution in which the blue quantum-dot structures 5B are dispersed; that is, a solution containing the blue quantum dots 51B and the first ligands 52B. The first solution may be synthesized of the blue quantum dots 51B and the first ligands 52B synthesized by various techniques. The blue quantum dots 51B and the first ligands 52B may be mixed together in a polar solvent such as water, so that the first solution may be synthesized. Otherwise, the first solution may be synthesized of the blue quantum dots 51B to which organic ligands different from the first ligands 52B are coordinated. The first ligands 52B in an excess amount may be mixed with a solution in which the blue quantum dots 51B are dispersed in a polar solvent. After that, the solution may be stirred, so that the first solution may be synthesized. In this case, the ligands coordinated to the blue quantum dots 51B substitute for the first ligands 52B, so that the blue quantum-dot structures 5B are synthesized in the solution.

Furthermore, in this embodiment, following Step S9, a second solution is synthesized (Step S10). The second solution is a solution in which the green quantum-dot structures 5G are dispersed; that is, a solution containing the green quantum dots 51G and the second ligands 52G. A method for synthesizing the second solution may be the method for synthesizing the first solution in which the blue quantum dots 51B may be replaced with the green quantum dots 51G and the first ligands 52B may be replaced with the second ligands 52G.

### Method for Manufacturing Display Device: Forming Blue Light-Emitting Layer

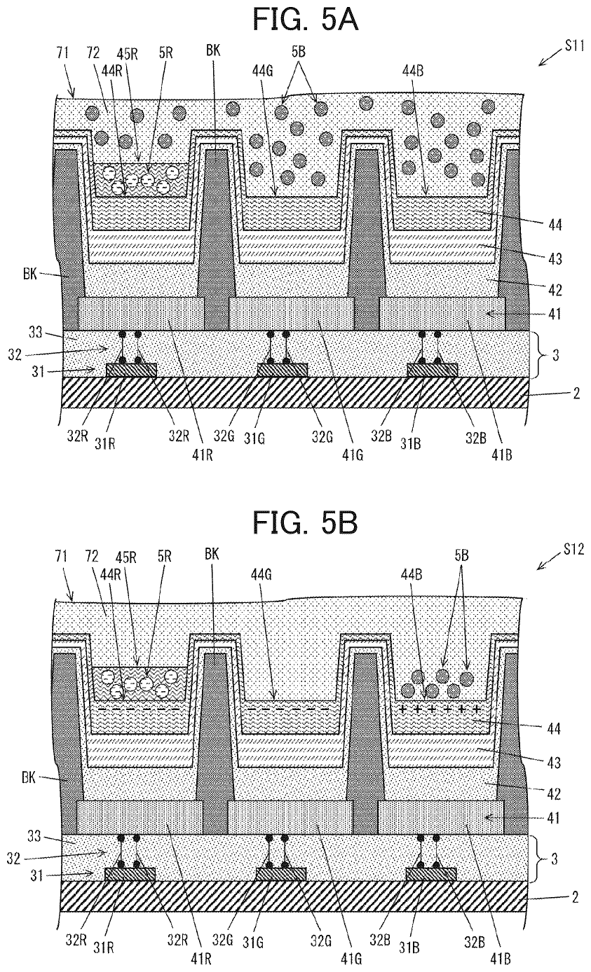

The red light-emitting layer 45R is formed, and the first solution and the second solution are synthesized. After that, in this embodiment, a multilayer stack is immersed in the first solution (Step S11). The multilayer stack includes the substrate 2 provided with the high dielectric layer 44 and the red light-emitting layer 45R. In FIG. 5A, Step S11 shows how the multilayer stack including the substrate 2 is immersed in a first solution 71. For example, the first solution 71 contains a plurality of the blue quantum-dot structures 5B dispersed in a first polar solvent 72. At Step S11, an upper face of the red light-emitting layer 45R in the multilayer stack and an upper face of the high dielectric layer 44 overlapping with the blue subpixel SPB and the green subpixel SPG in a plan view of the substrate 2 are exposed to the first solution 71 in which the plurality of blue quantum-dot structures 5B are dispersed.

Next, a voltage is applied to the anode 41B serving as the first anode (Step S12). The application of the voltage to the anode 41B is carried out through application of the voltage to the pixel circuit 31B by, for example, a method described later.

In particular, in this embodiment, the voltage is applied to the anode 41B so that the anode 41B becomes higher in potential than the anode 41R and the anode 41G. Hence, between the anode 41B and the other anodes 41, an electric field is formed in a direction from the anode 41B toward the other anodes 41.

Note that, because of the voltage applied to the anodes 41 as described above, the layers overlapping with the anode 41B in a plan view of the substrate 2; that is, the layers of the blue subpixel SPB, are polarized. In particular, the upper face of each of the layers is positively charged. In particular, the upper face of the high dielectric layer 44B having a high relative permittivity is positively charged more highly. Because of the high dielectric layer 44B whose upper face is positively charged, the electric field formed in the direction from the anode 41B toward the other anodes 41 becomes stronger.

Furthermore, because of the voltage applied to the anodes 41 as described above, the layers overlapping with the anode 41R and the anode 41G in a plan view of the substrate 2; that is, the layers of the red subpixel SPR and the green subpixel SPG, are polarized. In particular, the upper face of each of the layers is positively charged. In particular, the upper faces of the high dielectric layer 44R and the high dielectric layer 44G, both of which have a high relative permittivity, are negatively charged more highly. Because of the high dielectric layer 44R and the high dielectric layer 44G whose upper faces are negatively charged, the electric field formed in the direction from the anode 41B toward the other anodes 41 becomes stronger.

Here, in the first solution 71 in which the multilayer stack including the substrate 2 is immersed at Step S12, the blue quantum-dot structures 5B are dispersed. The blue quantum-dot structures 5B contain the blue quantum dots 51B to which the first ligands 52B having the negatively charged acidic groups 63 are coordinated. Hence, the electric field described above attracts the acidic groups 63 of the first ligands 52B to the anode 41B. Thus, as illustrated at Step S12 in FIG. 5B, the blue quantum-dot structures 5B including the blue quantum dots 51B are adsorbed onto the upper face of the high dielectric layer 44B formed in the blue subpixel SPB.

Note that, even if the first ligands 52B of the blue quantum-dot structures 5B are not negatively charged in the first solution 71, the first ligands 52B have the dipole moment M1. Hence, the electric field described above generates an attractive force between the first ligands 52B and the high dielectric layer 44B whose upper face is positively charged. Thus, also in the above case, the blue quantum-dot structures 5B are adsorbed onto the upper face of the high dielectric layer 44B.

Furthermore, the electric field generated between the anode 41R and the anode 41G is desirably small in view of reducing the adsorption of the blue quantum dots 51B to the red subpixels SPR and the green subpixels SPG. Hence, in order to reduce the electric field generated between the anode 41R and the anode 41G, the potentials of the anode 41R and the anode 41G may be substantially the same. Note that, as long as the adsorption of the blue quantum dots 51B to the red subpixel SPR and the green subpixel SPG is sufficiently reduced, a difference in potential may be found between the anode 41R and the anode 41G.

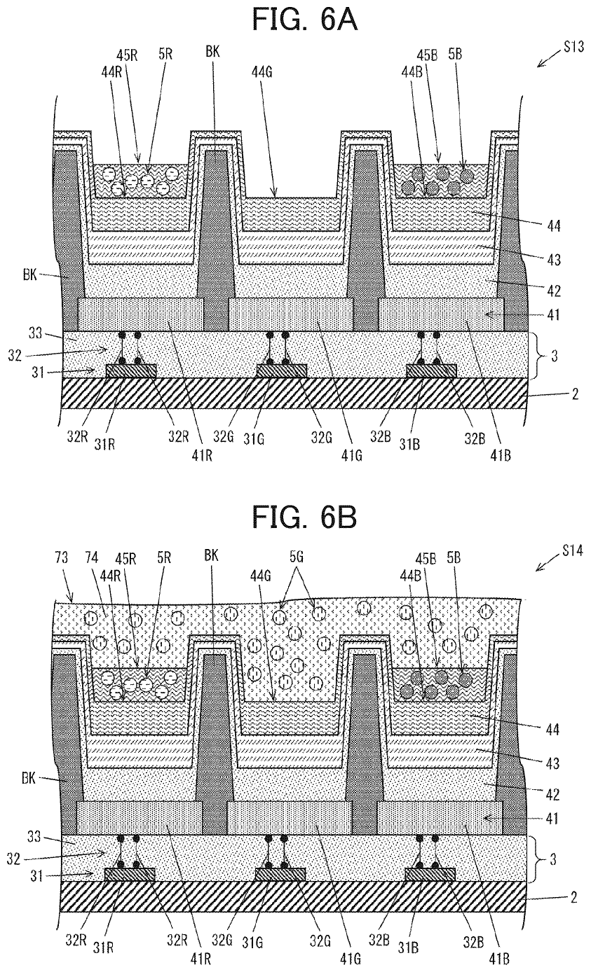

Next, the multilayer stack is rinsed (Step S13). The multilayer stack includes the substrate 2 provided with the high dielectric layer 44B whose upper face has the blue quantum-dot structures 5B adsorbed thereto At Step S13, the multilayer stack is removed from the first solution 71 and rinsed with, for example, a polar solvent containing, for example, the PGMEA. Hence, except for blue quantum-dot structures 5B adsorbed onto the upper face of the high dielectric layer 44B, the blue quantum-dot structures 5B adhering to, for example, the upper face of the red light-emitting layer 45R and the upper face of the high dielectric layer 44G are rinsed away. As can be seen, as illustrated at Step S13 in FIG. 6A, the blue light-emitting layer 45B is formed in the blue subpixel SPB.

### Method for Manufacturing Display Device: Method for Applying Voltage at Adsorption Step

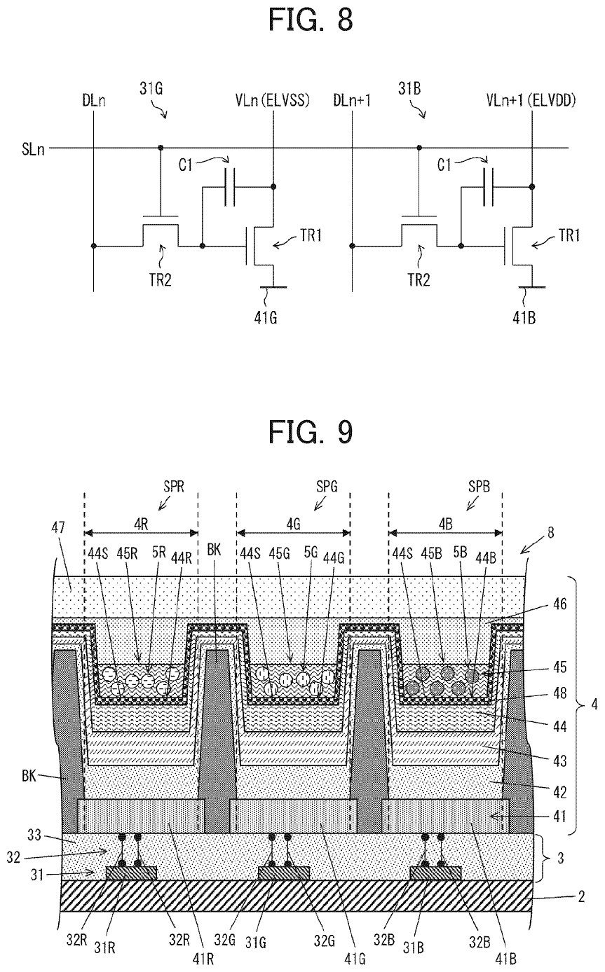

Described below with reference to FIG. 8 will be a specific method for applying a voltage to each of the anodes 41 at Step S12. FIG. 8 is an equivalent circuit diagram of pixel circuits and anodes 41 of the display device 1. In particular, FIG. 8 illustrates an equivalent circuit diagram of the pixel circuit 31G, the pixel circuit 31B, the anode 41G, and the anode 41B of the display device 1. Note that FIG. 8 also illustrates wires electrically connecting each of the pixel circuits 31 to the respective anodes 41.

In this embodiment, each of the pixel circuits 31 includes: a drive transistor TR1; a write transistor TR2; and a capacitor C1. In particular, in this embodiment, the drive transistor TR1 has a gate electrode connected to a source electrode of the write transistor TR2. Furthermore, the capacitor C1 is formed between a drain electrode of the drive transistor TR1 and the source electrode of the write transistor TR2. The source electrodes of the drive transistors TR1 are connected to the respective anodes 41, so that the pixel circuits 31 are connected to the respective anodes 41.

Moreover, the pixel circuit layer 3 according to this embodiment includes: a plurality of data lines DL; a plurality of power-supply voltage lines VL, and a plurality of scan signal lines SL. Each of the pixel circuits 31 is connected to a corresponding one of the data lines DL, the power-supply voltage lines VL, and the scan signal lines SL. In particular, each of the data lines DL is connected to the drain electrode of the write transistor TR2 of the corresponding pixel circuit 31. In addition, each of the power-supply voltage lines VL is connected to the drain electrode of the drive transistor TR1 of the corresponding pixel circuit 31. Furthermore, each of the scan signal lines SL is connected to the gate electrode of the write transistor TR2 of the corresponding pixel circuit 31.

Here, both the pixel circuit 31G and the pixel circuit 31B illustrated in FIG. 8 are connected to an operation signal line SLn. Moreover, the pixel circuit 31G is connected to a data line DLn and to a power-supply voltage line VLn, and the pixel circuit 31B is connected to a data line DLn+1 and to a power-supply voltage line VLn+1.

In a normal operation of the manufactured display device 1, for example, a high-level power supply voltage ELVDD is applied to each of the power-supply voltage lines VL, and a potential signal based on grayscale data of the corresponding subpixel is applied to each of the data lines DL. Hence, during a period in which each scan signal line SL is active, each data line DL supplies the corresponding anode 41 connected to the data line DL with the potential signal based on the grayscale data. Note that, for example, a low-level power supply voltage ELVSS is applied to the cathode 47 through a not-shown auxiliary power supply. As can be seen, the display device 1 individually drives the anodes 41 in accordance with the potential signals applied to the respective data lines DL, so as to individually control light to be emitted from the subpixels and display an image.

Whereas, at Step S12, as shown in FIG. 8, the low-level power supply voltage ELVSS is applied to the power-supply voltage line VLn connected to the pixel circuit 31G, and the high-level power supply voltage ELVDD is applied to the power-supply voltage line VLn+1 connected to the pixel circuit 31B. Hence, at Step S12, a voltage is applied to each of the pixel circuits 31.

At Step S12, for example, a driver used for the normal display of the display device 1 may be used for the application of a voltage as described above. In this case, the driver may switch a target, to which the low-level power supply voltage ELVSS is applied from the above auxiliary power supply, from the cathode 47 to the power-supply voltage line VLn, so as to achieve the application of a voltage as described above.

Furthermore, at Step S12, a predetermined voltage is applied to each data line DL and each scan signal line SL. The predetermined voltage is higher than threshold voltages of the drive transistor TR1 and the write transistor TR2 of the corresponding pixel circuit 31. As can be seen, a voltage is applied to each of the anodes 41 through application of the voltage to the corresponding pixel circuit 31 at Step S12. In particular, at Step S12, a voltage applied to the anode 41B can be higher than a voltage applied to the anode 41G.

Note that the pixel circuit 31R may be the same in configuration as either the pixel circuit 31G or the pixel circuit 31B. In this case, at Step S12, for example, the low-level power supply voltage ELVSS is applied to the power-supply voltage line VL connected to the pixel circuit 31R. Hence, at Step S12, a voltage applied to the anode 41B can be higher than a voltage applied to the anode 41R.

As can be seen, in this embodiment, the application of the voltage to each of the anodes 41 at a step of electrodeposition is carried out through application of the voltage to the corresponding pixel circuit 31 to be used when the display device 1 performs normal display. Thanks to such a feature, in this embodiment, the application of the voltage to each of the anodes 41 at the step of electrodeposition can be carried out with, for example, a driver used when the display device 1 performs normal display. Thus, the feature eliminates the need for preparation of, for example, an external power supply. Hence, in this embodiment, the step of electrodeposition can be carried out in a simpler manner.

As to the step of electrodeposition according to this embodiment, described is a method to apply a voltage to both the anode 41B and the anode 41G. However, the method may be any given method. For example, at the step of electrodeposition, the voltage may be applied to only one of the anode 41B or the anode 41G, so that a potential of the anode 41B is raised higher than a potential of the anode 41G. For example, at the step of electrodeposition, the anode 41G may be grounded, and, simultaneously, a predetermined positive voltage may be applied to the anode 41B.

Furthermore, at the step of electrodeposition according to this embodiment, described is a method for applying a voltage to both the anode 41B and the anode 41G through application of the voltage to both the pixel circuit 31B and the pixel circuit 31G. However, the method may be any given method. For example, at the step of electrodeposition, the voltage may be applied to only one of the pixel circuit 31B or the pixel circuit 31G. In this case, the voltage may be applied to only one of the anode 41B or the anode 41G.

The high-level power supply voltage ELVDD may be a reverse voltage of the low-level power supply voltage ELVSS. In other words, at the step of electrodeposition, the voltage to be applied to the anode 41B may be a reverse voltage of the voltage to be applied to the anode 41G. Hence, in this embodiment, at the step of electrodeposition, a voltage is applied to each of the anodes 41 in a simpler manner.

Note that the configuration of each of the pixel circuits 31 may be any given configuration. As long as a voltage applied to the anode 41B can be higher than voltages applied to the anode 41R and the anode 41G, the pixel circuit 31 may have various kinds of known configurations. For example, the pixel circuit layer 3 may have an initialization signal line supplied with an initialization signal for initializing a potential signal to be applied to each of the anodes 41. In this case, each pixel circuit 31 may include an initialization transistor driven by the initialization signal supplied to the initialization signal line.

### Method for Manufacturing Display Device: Forming Green Light-Emitting Layer

Next, a multilayer stack is immersed in the second solution (Step S14). The multilayer stack includes the substrate 2 provided with the blue light-emitting layer 45B. In FIG. 6B, Step S14 shows how the multilayer stack including the substrate 2 is immersed in a second solution 73. For example, the second solution 73 contains a plurality of the green quantum-dot structures 5G dispersed in a second polar solvent 74. At Step S14, upper faces of the red light-emitting layer 45R and the blue light-emitting layer 45B in the multilayer stack and the upper face of the high dielectric layer 44 overlapping with the green subpixel SPG in a plan view of the substrate 2 are exposed to the second solution 73 in which the plurality of green quantum-dot structures 5G are dispersed.

Next, a voltage is applied to the anode 41G serving as the second anode (Step S15). The application of the voltage to the anode 41G is carried out through application of the voltage to the pixel circuit 31G with a not-shown driver by a method to be described later.

In particular, in this embodiment, the voltage is applied to the anode 41G so that the anode 41G becomes lower in potential than the other anodes 41. Hence, between the anode 41G and the other anodes 41, an electric field is formed in a direction from the other anodes 41 toward the anode 41G.

At Step S15, the voltage may be applied to each of the anodes 41 by the same method used when the voltage is applied to each of the anodes 41 at Step S12 except for the voltage applied to the anode 41R. For example, at Step S15, the voltage is applied to the anode 41R so that the anode 41R becomes higher in potential than the anode 41G. For example, at Step S15, the voltage is applied by the same method used when the voltages are applied at Step S12 except that the power-supply voltage to be applied to the power-supply voltage line VL connected to the pixel circuit 31R is the high-level power supply voltage ELVDD.

At Step S15, the upper face of the high dielectric layer 44G is negatively charged highly, and the upper faces of the high dielectric layer 44R and the high dielectric layer 44B are positively charged highly. Hence, the electric field formed in the direction from the other anodes 41 toward the anode 41G becomes stronger.

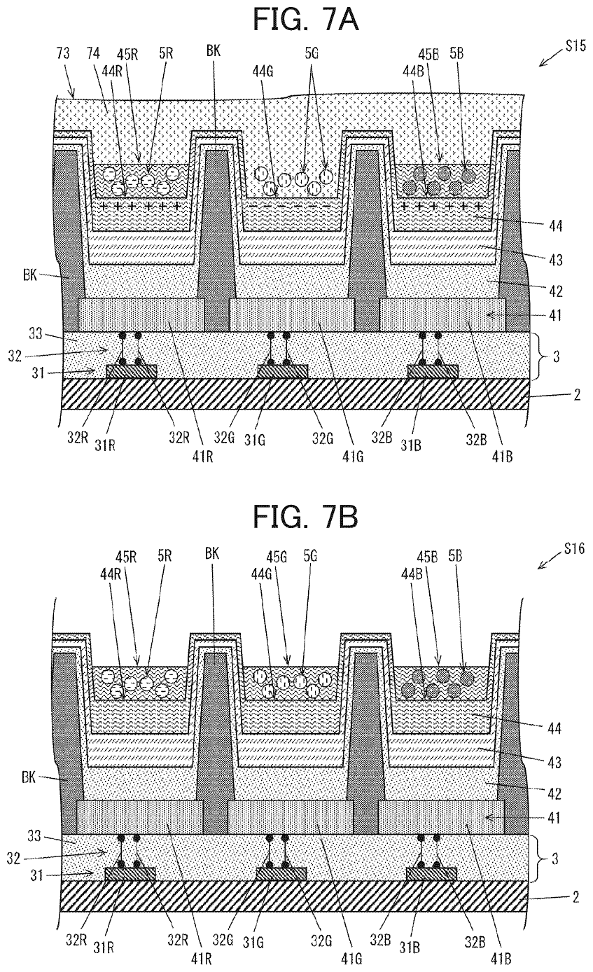

Here, in the second solution 73 in which the multilayer stack including the substrate 2 is immersed at Step S15, the green-quantum dot structures 5G are dispersed. The green quantum-dot structures 5G contain the blue quantum dots 51G to which the second ligands 52G having the positively charged basic groups 64 are coordinated. Hence, the electric field described above attracts the basic groups 64 of the second ligands 52G to the anode 41G. Thus, as illustrated at Step S15 in FIG. 7A, the green quantum-dot structures 5G including the green quantum dots 51G are adsorbed onto the upper face of the high dielectric layer 44G formed in the green subpixel SPG.

Note that, even if the second ligands 52G of the green quantum-dot structures 5G are not negatively charged in the second solution 73, the second ligands 52G have the dipole moment M2. Hence, the electric field described above generates an attractive force between the second ligands 52G and the high dielectric layer 44G whose upper face is negatively charged. Thus, also in the above case, the green quantum-dot structures 5G are adsorbed onto the upper face of the high dielectric layer 44G.

Next, the multilayer stack is rinsed (Step S16). The multilayer stack includes the substrate 2 provided with the high dielectric layer 44G whose upper face has the green quantum-dot structures 5G adsorbed thereto. Step S16 may be carried out by the same method as Step S13. Hence, except for green quantum-dot structures 5G adsorbed onto the upper face of the high dielectric layer 44G, the green quantum-dot structures 5G adhered to, for example, the upper face of the red light-emitting layer 45R and the upper face of the blue light-emitting layer 45B are rinsed away. Thus, as illustrated at Step S16 in FIG. 7B, the green light-emitting layer 45G is formed in the subpixel SPG, and the step of forming the light-emitting layer 45 ends.

Method for Manufacturing Display Device: Forming Electron Transport Layer and after

Next, on the light-emitting layer 45, the electron transport layer 46 is formed (Step S17). In forming the electron transport layer 46, for example, as seen at Step S6 or Step S7, an electron-transporting material may be applied and deposited at a position on the light-emitting layer 45, so as to form the electron transport layer 46.

Next, on the electron transport layer 46, the cathode 47 is formed (Step S18). The cathode 47 may be, for example, a thin film formed of such a material as metal material. The metal material may be deposited by, for example, sputtering over the electron transport layer 46, in order to form the cathode 47. The cathode 47 may be formed to be electrically connected to the auxiliary power supply described above. Hence, the steps of manufacturing the display device 1 end.

### Advantageous Effects of Display Device

The blue light-emitting layer 45B of the display device 1 has the blue quantum-dot structures 5B each including: the blue quantum dot 51B; and the first ligand 52B coordinated to the blue quantum dot 51B. Furthermore, the green light-emitting layer 45G has the green quantum-dot structures 5G each including: the green quantum dot 51G; and the second ligand 52G coordinated to the green quantum dot 51G.

The first ligand 52B has the dipole moment M1 in a direction from the main chain 61 toward the coordinating functional group 62. Hence, at Step S12, an attractive force is generated between the anode 41B and the first ligand 52B coordinated to the blue quantum dot 51B. Hence, at Step S12, even if the attractive force is not generated between the anode 41B and the blue quantum dot 51B, the blue quantum dot 51B is adsorbed onto the blue subpixel SPB.

The second ligand 52G has the dipole moment M2 in a direction from the coordinating functional group 62 toward the main chain 61. Hence, at Step S15, an attractive force is generated between the anode 41G and the second ligand 52G coordinated to the green quantum dot 51G. Hence, at Step S15, even if the attractive force is not generated between the anode 41G and the green quantum dot 51G, the green quantum dot 51G is adsorbed onto the green subpixel SPG.

Furthermore, a repulsive force is generated between the first ligand 52B and the anode 41G at Step S12 and between the first ligand 52B and the anode 41G at Step S15. Hence, at Step S12 and Step S15, the repulsive force can reduce the risk of the quantum dots being adsorbed onto subpixels emitting light in different colors.

As a result, each of the blue light-emitting layer 45B and the green light-emitting layer 45G of the display device 1 can be efficiently formed also by electrodeposition.

Moreover, the first ligand 52B has the acidic group 63 negatively charged in the solution, and the second ligand 52G has the basic group 64 positively charged in the solution. Hence, at the step of electrodeposition, even if a polarity is observed in the solvent of the solution in which the multilayer stack including the substrate 2 is immersed, the first ligand 52B is adsorbed to the blue subpixel SPB more strongly than to the solvent, and the second ligand 52G is adsorbed to the green subpixel SPG more strongly than to the solvent. As a result, the above feature makes it possible to form each of the blue light-emitting layer 45B and the green light-emitting layer 45G while reducing intrusion of the solvent even if electrodeposition is used. Hence, the yield improves.

In particular, the first ligand 52B and the second ligand 52G respectively have the acidic group 63 and the basic group 64 each provided to one end of the main chain 61 across from the coordinating functional group 62. Such a feature further increases a distance between the blue quantum dot 51B and the acidic group 63 and a distance between the green quantum dot 51G and the basic group 64. Hence, at the step of electrodeposition, the attractive force further increases between the first ligand 52B and each anode 41 and between the second ligand 52G and each anode 41. Such a feature further improves the yields of the blue light-emitting layers 45B and the green light-emitting layers 45G.

In this embodiment, the red light-emitting layer 45R has the red quantum-dot structures 5R each including: the red quantum dot 51R; and the third ligand 52R having no polarities and coordinated to the red quantum dot 51R. The third ligand 52R has no polarities. That is why, at the step of electrodeposition described above, an attractive force and a repulsive force are less likely to be generated between the third ligand 52R and each anode 41. Hence, the third ligand 52R reduces the risk that the red quantum dots 51R, which have already been stacked in the subpixel SPR at the step of electrodeposition, are liberated into the solution and flow into another subpixel. Thus, the red light-emitting layer 45R reduces color mixture at the step of electrodeposition and improves the overall yield of the light-emitting layers 45.

In particular, the third ligand 52R is a neutral ligand neither negatively nor positively charged in the solution. Hence, the third ligand 52R can further reduce the attractive force and the repulsive force between the third ligand 52R and each of the anodes 41 at the step of electrodeposition, thereby further decreasing color mixture at the step of electrodeposition.

Typically, blue quantum dots and green quantum dots are more likely to deteriorate than red quantum dots. In particular, compared with red quantum dots, blue quantum dots and green quantum dots are less likely to be resistant to a developing solution or a rinsing solution to be used for such a technique as a lift-off technique. In this embodiment, the red light-emitting layer 45R is formed by such a technique as the lift-off technique. After that, the blue light-emitting layer 45B and the green light-emitting layer 45G can be formed by electrodeposition. In this way, this embodiment can reduce deterioration of the blue light-emitting layer 45B and the green light-emitting layer 45G, which could occur at the step of forming the red light-emitting layer 45R, thereby successfully improving the yield of the light-emitting layers 45.

Note that, typically, blue quantum dots are more likely to deteriorate than green quantum dots. Hence, in this embodiment, the step of forming the green light-emitting layer 45G may be carried out prior to the step of forming the blue light-emitting layer 45B. In this case, Step S14 to Step S16 may be carried out prior to Step S11 to Step S13. The above manufacturing method can keep the blue light-emitting layer 45B from deterioration that could be caused by the step of forming the green light-emitting layer 45G, thereby successfully improving the yield of the light-emitting layers 45.

The display device 1 according to this embodiment includes the high dielectric layer 44 positioned toward the anode 41 with respect to the light-emitting layer 45. Hence, at Step S12 and Step S15, a voltage is applied to the anode 41 so that the high dielectric layer 44 is dielectrically induced strongly, and the quantum dots are adsorbed onto the subpixels more efficiently.

As a result, each of the blue light-emitting layer 45B and the green light-emitting layer 45G of the display device 1 can be efficiently formed also by electrodeposition.

A relative permittivity of the high dielectric layer 44 is higher than a relative permittivity of each of the layers included in the light-emitting element 4 and positioned below the high dielectric layer 44; that is, the layers positioned toward the substrate 2. Furthermore, the relative permittivity of the high dielectric layer 44 is higher than a relative permittivity of the bank BK. Hence, at the step of electrodeposition, the high dielectric layer 44 is polarized more strongly than the bank BK and the layers positioned toward the substrate 2 with respect to the high dielectric layer 44. The upper face of the high dielectric layer 44 is charged more highly. Thus, at the step of electrodeposition, the high dielectric layer 44 adsorbs the quantum dots more strongly, and improves the yield of the light-emitting layers 45.

In particular, because the relative permittivity of the high dielectric layer 44 is higher than the relative permittivity of the bank BK, a stronger attractive force can be exerted between the high dielectric layer 44 and each of the quantum dots than between the bank BK and each of the quantum dots. Such a feature can reduce the quantum dots adhering to the bank BK. Hence, thanks to the above feature, the high dielectric layer 44 reduces the quantum dots left on the bank BK facing a subpixel different from a subpixel to which the quantum dots are to be originally adsorbed. Thus, thanks to the above feature, the high dielectric layer 44 reduces color mixture in the light-emitting layers 45 and improves the yield of the light-emitting layers 45.

In this embodiment, the relative permittivity of the high dielectric layer 44 is, for example, 1.0 or higher. Thanks to such a feature, the high dielectric layer 44 adsorbs the quantum dots more reliably at the step of electrodeposition, and improves the yield of the light-emitting layers 45.

### Second Embodiment

### Hydrophobic Layer

A display device 8 according to this embodiment will be described, with reference to FIG. 9. FIG. 9 illustrates a schematic sectional side view of the display device 8 according to this embodiment. The schematic sectional side view illustrates a cross-section of the display device 8 corresponding to the cross-section of the display device 1 illustrated in the schematic sectional side view 101 in FIG. 1A. The display device 8 according to this embodiment is the same in configuration as the display device 1 according to the previous embodiment, except that the high dielectric layer 44 of the light-emitting element 4 includes a hydrophobic layer 48 toward the light-emitting layer 45.

The hydrophobic layer 48 is hydrophobic, and in particular, repellent to a polar solvent such as water. Hence, a surface 44S included in the high dielectric layer 44 and having contact with the light-emitting layer 45 is hydrophobic. The hydrophobic layer 48 may contain a fluorine-based material containing, for example, silicon oxide and silicon nitride.

Note that, in the high dielectric layer 44 in FIG. 9, the hydrophobic layer 48 is provided only in the vicinity of the surface 44S in contact with the light-emitting layer 45. However, as long as the surface 44S is hydrophobic, the high dielectric layer 44 may have any given configuration. For example, in this embodiment, the high dielectric layer 44 may contain a hydrophobic material in addition to a material with a high permittivity. Hence, the whole high dielectric layer 44 including the surface 44S may be hydrophobic.

A method for method for manufacturing the display device 8 according to this embodiment may be performed when some of the steps shown in FIG. 3 are carried out as will be described below. In the method for manufacturing the display device 8 according to this embodiment, Step S1 to Step S6 may be respectively the same as Step S1 to Step S6 of the method for manufacturing the display device 1 according to the previous embodiment.

At Step S7 of the method for manufacturing the display device 8 according to this embodiment, for example, a material with a high permittivity may be applied and deposited. After that, a water-repellent material is applied and deposited, so as to form the high dielectric layer 44 including the hydrophobic layer 48. Alternatively, at Step S7, for example, the high dielectric layer 44 may be formed. After that, the upper face of the high dielectric layer 44 may be modified, so that the high dielectric layer 44 may be formed to include the hydrophobic layer 48. Otherwise, at Step S7, for example, a material with a high permittivity and a hydrophobic material may be mixed together, and the mixture may be applied and deposited to form the high dielectric layer 44 that is hydrophobic as a whole, including the surface 44S.

At Step S8 of the method for manufacturing the display device 8 according to this embodiment, the red light-emitting layer 45R is formed above the hydrophobic layer 48 of the high dielectric layer 44R. Hence, at Step S8, in order to allow the solution containing the red quantum-dot structures 5R to form a better film, the solvent of the solution may contain a nonpolar solvent. In this case, at Step S8, even if the solution containing the red quantum-dot structures 5R forms a film on the hydrophobic layer 48, the solution is likely to wet and spread on the hydrophobic layer 48.

In the method for manufacturing the display device 8 according to this embodiment, Step S9 and Step S10 may be respectively the same as Step S9 and Step S10 of the method for manufacturing the display device 1 according to the previous embodiment.

At Step S11 of the method for manufacturing the display device 8 according to this embodiment, the hydrophobic layer 48 of the high dielectric layer 44G and the high dielectric layer 44B is exposed to the first solution 71. In this embodiment, the first solution 71 contains the first polar solvent 72. That is why the first solution 71 is less likely to wet and spread on the hydrophobic layer 48. However, at Step S12, the voltage is applied as described above, and the blue quantum-dot structures 5B are adsorbed onto the high dielectric layer 44B. Hence, at Step S12, the first solution 71 wets and spreads on the hydrophobic layer 48 of the high dielectric layer 44B.

In this embodiment, at Step S13, the layers above the substrate 2 may be rinsed while the voltage is kept applied as described above. Hence, at Step S13, the first solution 71 can be easily rinsed away from the hydrophobic layer 48, of the high dielectric layer 44G, on which the first solution 71 is less likely to spread, and the blue quantum-dot structures 5B can be less likely to flow out from the top of the hydrophobic layer 48 of the high dielectric layer 44B. Thus, this embodiment can reduce intrusion of the blue quantum-dot structures 5B into the green light-emitting layer 45G, and simultaneously form the blue light-emitting layer 45B in high quality and improve the yield of the light-emitting layers 45.

At Step S14 of the method for manufacturing the display device 8 according to this embodiment, the hydrophobic layers 48 of the high dielectric layer 44G is exposed to the second solution 73. In this embodiment, the second solution 73 contains the second polar solvent 74. That is why the second solution 73 is less likely to wet and spread on the hydrophobic layer 48. However, at Step S15, the voltage is applied as described above, and the green quantum-dot structures 5G are adsorbed onto the high dielectric layer 44G. Hence, at Step S15, the second solution 73 wets and spreads on the hydrophobic layer 48 of the high dielectric layer 44G.

In this embodiment, at Step S16, the layers above the substrate 2 may be rinsed while the voltage is kept applied as described above. Hence, at Step S16, the green quantum-dot structures 5G can be less likely to flow out from the top of the hydrophobic layer 48 of the high dielectric layer 44G. Thus, this embodiment can form the green light-emitting layer 45G in higher quality and improve the yield of the light-emitting layers 45.

In the method for manufacturing the display device 8 according to this embodiment, Step S17 and Step S18 may be respectively the same as Step S17 and Step S18 of the method for manufacturing the display device 1 according to the previous embodiment.

The display device 8 according to this embodiment includes: the blue light-emitting layer 45B having the blue quantum-dot structures 5B; and the green light-emitting layer 45G having the green quantum-dot structures 5G, as seen in the display device 1 according to the previous embodiment, Furthermore, the display device 8 includes the high dielectric layer 44 toward the substrate 2 with respect to the light-emitting layer 45. Hence, because of the same reasons as described in the previous embodiment, each of the blue light-emitting layer 45B and the green light-emitting layer 45G of the display device 8 can be efficiently formed also by electrodeposition.

Moreover, as to the display device 8 according to this embodiment, the high dielectric layer 44 includes the hydrophobic layer 48. Thus, the surface 44S included in the high dielectric layer 44 and having contact with the light-emitting layer 45 is hydrophobic. Thanks to such a feature, the display device 8 can be provided with the light-emitting layer 45 in high quality with less color mixture at the step of electrodeposition. Hence, the light-emitting layer 45 can be formed by electrodeposition with more efficiency.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A display device, comprising:
a substrate; and a first light-emitting element and a second light-emitting element on the substrate,
wherein the first light-emitting element has a first light-emitting layer containing: a first quantum dot; and a first ligand having a dipole moment in a direction from a main chain toward a coordinating functional group, and
the second light-emitting element has a second light-emitting layer containing: a second quantum dot; and a second ligand having a dipole moment in a direction from a coordinating functional group toward a main chain.

2. The display device according to claim 1,
wherein the first ligand has an acidic group, and the second ligand has a basic group.

3. The display device according to claim 2,
wherein the first ligand has the acidic group at an end of the main chain across from the coordinating functional group, and the second ligand has the basic group at an end of the main chain across from the coordinating functional group.

4. The display device according to claim 1, further comprising
a third light-emitting element on the substrate,
wherein the third light-emitting element has a third light-emitting layer containing: a third quantum dot; and a third ligand that is non-polar.

5. The display device according to claim 4,
wherein the third ligand is neutral in a polar solvent.

6. The display device according to claim 4,
wherein one of the first quantum dot or the second quantum dot is a blue quantum dot, an other one of the first quantum dot or the second quantum dot is a green quantum dot, and the third quantum dot is a red quantum dot.

7-12. (canceled)

13. A display device, comprising:
a substrate; and a first light-emitting element and a second light-emitting element on the substrate,
wherein the first light-emitting element has: a first light-emitting layer containing a first quantum dot, and a first ligand having a dipole moment in a direction from a main chain toward a coordinating functional group; and a first high dielectric layer positioned toward the substrate with respect to the first light-emitting layer, and
the second light-emitting element has: a second light-emitting layer containing a second quantum dot, and a second ligand having a dipole moment in a direction from a coordinating functional group toward a main chain; and a second high dielectric layer positioned toward the substrate with respect to the second light-emitting layer.

14. A method for manufacturing a display device, the method comprising:
preparing a substrate layer;
forming a first electrode and a second electrode to the substrate;
forming high dielectric layers to the substrate, each of the high dielectric layers overlapping with a corresponding one of the first electrode and the second electrode in a plan view of the substrate;
synthesizing a first solution containing a first quantum dot and a first ligand having a dipole moment in a direction from a main chain toward a coordinating functional group;
synthesizing a second solution containing a second quantum dot and a second ligand having a dipole moment in a direction from a coordinating functional group toward a main chain;
immersing, in the first solution, the substrate to which the high dielectric layers are formed;
applying a voltage to at least one of the first electrode or the second electrode of the substrate immersed in the first solution so that the first quantum dot is adsorbed onto the high dielectric layer overlapping with the first electrode in a plan view of the substrate;
immersing, in the second solution, the substrate to which the high dielectric layers are formed; and
applying a voltage to at least one of the first electrode or the second electrode of the substrate immersed in the second solution so that the second quantum dot is adsorbed onto the high dielectric layer overlapping with the second electrode in a plan view of the substrate.

15. The method for manufacturing the display device according to claim 14, further comprising forming a first pixel circuit and a second pixel circuit,
wherein when the first electrode and the second electrode are formed to the substrate, the first electrode and the first pixel circuit are electrically connected together and the second electrode and the second pixel circuit are electrically connected together, and
in each of the adsorption of the first quantum dot and the adsorption of the second quantum dot, at least one of the applying the voltage to the first electrode through application of the voltage to the first pixel circuit or the applying the voltage to the second electrode through application of the voltage to the second pixel circuit is carried out.

16. The method for manufacturing the display device according to claim 15,
in at least one of the adsorption of the first quantum dot or the adsorption of the second quantum dot, the voltage to be applied to the first electrode is a reverse voltage of the voltage to be applied to the second electrode.

17. The display device according to claim 13,
wherein the first high dielectric layer is in contact with the first light-emitting layer,
the second high dielectric layer is in contact with the second light-emitting layer, and
the surfaces of the first high dielectric layer and the second high dielectric layer on the sides of the light-emitting layers are hydrophobic.

18. The display device according to claim 13,
further comprising hydrophobic layers between the first light-emitting layer and the first high dielectric layer and between the second light-emitting layer and the second high dielectric layer.
